(19) United States
(12) Patent Application Publication
(10) Pub. No.: US 2012/0322195 A1
(43) Pub. Date: Dec. 20, 2012

(54) METHOD FOR PRODUCING SOLAR MODULES

(75) Inventors: Gerd Bergmann, Hamburg (DE); Michael Herrmann, Koln (DE); Arndt Kremers, Wurselen (DE)

(73) Assignee: LANXESS DEUTSCHLAND GMBH, Leverkusen (DE)

(21) Appl. No.: 13/389,013

(22) PCT Filed: Aug. 3, 2010
(86) PCT No.: PCT/EP10/61299

§ 371 Date: Aug. 12, 2012

(30) Foreign Application Priority Data
Aug. 7, 2009 (DE) 10 2009 036 533.6

(51) Int. Cl. H01L 31/18

(52) U.S. Cl. 438/64; 257/E31.11

(57) ABSTRACT

The present invention relates to a process for producing solar modules.

### CROSS REFERENCE TO RELATED PATENT APPLICATIONS

The present patent application claims the right of priority under 35 U.S.C. §119 (a)-(d) and 35 U.S.C. §365 of International Application No. PCT/EP2010/061299, filed Aug. 3, 2010, which was published in German as International Patent Publication No. WO 2011/15584A1 on Feb. 10, 2011, which is entitled to the right of priority of German Patent Application No. DE 10 2009 036 533.8 filed on Aug. 7, 2009.

The present invention relates to a process for producing solar modules.

Solar modules are composed essentially of a composite of transparent materials, solar cells, current-conducting components and weather-resistant protective devices. Different solar modules, such as film-backed modules, laminated glass-glass modules, glass-glass modules in casting resin technology, glass-glass modules in composite safety film technology, and thin-layer modules, are known to those skilled in the art.

In a solar module, the solar cell is generally surrounded on both sides by polymeric embedding material. These polymeric embedding materials consist frequently of, for example, an α-olefin-vinyl acetate copolymer. On the top side of the solar cell is a transparent substrate consisting of for example, a single pane of safety glass. On the bottom side of the solar cell is generally a protective layer consisting of a weather-resistant polymer film.

EP 1 184 912 A1 describes the production of solar modules, wherein transparent substrates are laminated with polymeric embedding materials consisting of α-olefin-vinyl acetate copolymers, solar cells, further polymeric embedding materials and a protective layer are layered one on top of another, and laminated in one process step. EP 1 184 912 A1 further states that an α-olefin-vinyl acetate copolymer, especially ethylene-vinyl acetate copolymer (EVA), with a high vinyl acetate content is particularly tacky, and exact positioning of the substrates, of the olefin-vinyl acetate film and of the solar cells to produce the solar module becomes difficult. This effect is enhanced by the fact that EVA copolymers with a vinyl acetate content of ≧40% are free-flowing and, as a result, complicate the process of embedding the solar cells. An exact arrangement of the individual components is, however, extremely important since the energy efficiency of the solar module is otherwise reduced, and the incorrect positionings can lead to damage to the solar cells. The resulting flawed solar modules would have to be discarded, which gives rise to additional costs.

Generally, the positioning of the transparent substrates, of the polymeric embedding materials, consisting of α-olefin-vinyl acetate copolymers, of the solar cells, of further polymeric embedding materials consisting of α-olefin-vinyl acetate copolymer, and of the opaque substrate in the production of solar modules constitutes a problem since the exact positioning of these five components with respect to one another, owing to the material properties, more particularly owing to the tackiness and the handling, frequently leads to uncorrectable shifts of the components, resulting in flawed solar modules.

It is therefore an object of the present invention to provide a process for precise and effective production of solar modules, with which the disadvantages of the prior art can be overcome.

It has now been found that, surprisingly, the process according to the invention can produce solar modules with good precision and with low time consumption, using separately manufactured components consisting of polymeric embedding material and substrate.

The invention therefore provides a process for producing solar modules, in which in a step a),

a transparent or opaque substrate is laminated with an embedding material composed of at least one α-olefin-vinyl acetate copolymer having a vinyl acetate content of ≧25% by weight, based on the total weight of the α-olefin-vinyl acetate copolymer, to give a component and,
in a second step b),
a component produced from transparent substrate in step a) and a component produced from opaque substrate in step a) are laminated with at least one solar cell positioned between the transparent and the opaque component to give the solar module.

Further references to α-olefin-vinyl acetate copolymers which occur in the text always relate to α-olefin-vinyl acetate copolymers with a vinyl acetate content of ≧25% by weight based on the total weight of the α-olefin-vinyl acetate copolymers, except when it has explicitly been defined differently.

In a preferred embodiment of the invention, the embedding material comprises at least one additive.

The embedding material may contain preferably 1% by weight to 70% by weight of at least one α-olefin-vinyl acetate copolymer and 0% by weight to 30% by weight of at least one additive, based on the total weight of the embedding material. It more preferably contains 1% by weight to 80% by weight of at least one α-olefin-vinyl acetate copolymer and 0% by weight to 20% by weight of at least one additive, based on the total weight of the embedding material. The embedding material most preferably comprises 90% by weight to 100% by weight of at least one α-olefin-vinyl acetate copolymer and 0-10% by weight of at least one additive, based in each case on the total weight of the embedding material. The sum of the α-olefin-vinyl acetate copolymer used and/or of the additive(s) is 100% by weight, based on the total weight of the embedding material.

For example and with preference, the embedding material may contain one, two, three or more α-olefin-vinyl acetate copolymers based on the total weight of the α-olefin-vinyl acetate copolymer. Preference is given to mixtures of two or more different α-olefin-vinyl acetate copolymers. Particular preference is given, however, to using only one α-olefin-vinyl acetate copolymer.

The embedding material preferably contains at least one α-olefin-vinyl acetate copolymer with vinyl acetate copolymer contents of ≧40% by weight, more preferably vinyl acetate contents of ≧45% by weight, based in each case on the total weight of the α-olefin-vinyl acetate copolymers. The vinyl acetate content of the α-olefin-vinyl acetate copolymers used is typically ≧25% by weight to 98% by weight, preferably ≧40% by weight to 98% by weight, more preferably ≧45% by weight to 98% by weight, and the α-olefin content 2% by weight to ≦75% by weight, preferably 2% by weight to ≦60% by weight, more preferably 2% by weight to ≦55% by weight, where the total amount of vinyl acetate and α-olefin is 100% by weight.

The α-olefins used in the α-olefin-vinyl acetate-copolymer used in the embedding material may be all known α-olefins. The α-olefin is preferably selected from ethene, propene, butene, especially n-butene and i-butene, pentene, hexene, especially 1-hexene, heptene and octene, especially 1-octene. It is also possible to use higher homologs of the α-olefins mentioned as α-olefins in the α-olefin-vinyl acetate copolymers used in the embedding material. The α-olefins may additionally bear substituents, especially C₁-C₅-alkyl radicals. However, the α-olefins preferably do not bear any further substituents.

Preferred α-olefins are ethene and propene, particular preference being given to using ethene as the α-olefin in the α-olefin-vinyl acetate copolymers used in the embedding material. The α-olefin-vinyl acetate copolymer used with preference in the inventive component is therefore an ethylene-vinyl acetate copolymer.

The embedding material used is more preferably exclusively an ethylene-vinyl acetate copolymer. In that case, the latter has a vinyl acetate content of ≧25% by weight to 98% by weight, preferably ≧40% by weight to 98% by weight, more preferably ≧45% by weight to 98% by weight, and an ethylene content of 2% by weight to ≦75% by weight, preferably 2% by weight to ≦60% by weight, more preferably 2% by weight to ≦55% by weight.

For example and with preference, the additives are selected from the group of peroxides, light stabilizers, silanes, aging stabilizers, photoinitiators such as benzophenones, and coagents for increasing the crosslinking density, such as triallyl cyanurate or triallyl isocyanurate, or from mixtures of these materials.

The embedding material in the process according to the invention most preferably comprises at least one further additive when the α-olefin-vinyl acetate copolymer of the embedding material contains a vinyl acetate content between ≧25% by weight and ≦40% by weight, based on the total weight of the α-olefin-vinyl acetate copolymer.

Suitable preparation processes for α-olefin-vinyl acetate copolymers are specified in EP-A 0 341 499, EP-A 0 510 478 and DE-A 38 25 450.

The α-olefin-vinyl acetate copolymers with a vinyl acetate content of ≧40% by weight, which are used with preference in the process according to the invention, are prepared by a solution polymerization process known from DE 2 031 662 A2.

The α-olefin-vinyl acetate copolymers used in the process according to the invention, preferably ethylene-vinyl acetate copolymers with a vinyl acetate content of ≧40% by weight, generally have MFI values (g/10 min), measured to ISO 1133 at 190° C. and a load of 21.1 N, of 1 to 40, preferably 1 to 35, more preferably 2 to 6.

The Mooney viscosities of the α-olefin-vinyl acetate copolymers used in the process according to the invention are, according to DIN 53523 mL 1+4, at 100° C., generally 3 to 50 and preferably 4 to 35 Mooney units.

The number-average molecular weight of the α-olefin-vinyl acetate copolymers used in the process according to the invention is, determined by means of GPC (gel-permeation chromatography), for example from 5000 g/mol to 200 000 g/mol, preferably 10 000 g/mol to 100 000 g/mol.

In the process according to the invention for producing solar modules, particular preference is given to using ethylene-vinyl acetate copolymers, which are commercially available, for example, under the trade names Levapren® or Levamelt® from Lanxess Deutschland GmbH.

The ethylene-vinyl acetate copolymers used in the process according to the invention for producing solar modules are more preferably Levamelt 450, Levamelt 452, Levamelt 456, Levamelt 500, Levamelt® 600, Levamelt 686, Levamelt® 700, Levamelt® 800 and Levamelt® 900 with 45±2% by weight of vinyl acetate and an MFI of 1-5, 45±2% by weight of vinyl acetate with an MFI of 5 to 15, 45±2% by weight of vinyl acetate with an MFI of 15-35, 50±2% by weight of vinyl acetate, 60±2% by weight of vinyl acetate, 68±2% by weight of vinyl acetate with an MFI of 15-35, 70±2% by weight of vinyl acetate, 80±2% by weight of vinyl acetate or 90±2% by weight of vinyl acetate.

The substrate may be glass, polycarbonate, polyester, polyvinyl fluoride, polyvinyl fluoride polymer laminates, polyvinylidene fluoride or polyethylene terephthalate, or mixtures of these materials. Some of these polymers, according to the composition and processing, may have transparent or/and opaque properties. The preparation of these polymers and the properties thereof are known to those skilled in the art.

A transparent substrate is preferably used in the component when this component is mounted on the side facing the sun. All transparent substrates known to those skilled in the art are suitable, for example and with preference glass, polycarbonate, polyester, polyvinyl fluoride, polyvinylidene fluoride, polyethylene terephthalate or mixtures of these materials. The transparent materials are preferably glass, polyvinyl fluoride polymer laminates and polyethylene terephthalate. Suitable transparent substrates are more preferably glass panes, very particular preference being given to using single-pane safety glass.

An opaque substrate is preferably used in the component when this component is mounted on the underside of the solar module, i.e. on the side facing away from the sun. The opaque substrate is preferably polyester, polyvinyl fluoride, polyvinylidene fluoride or polyethylene terephthalate. The opaque substrate is more preferably a polymer film, especially a polymer composite film, for example formed from polyvinyl fluoride, e.g. Tedlar® from DuPont, polyester, polyvinylidene fluoride, e.g. Kynar® from Arkema, or polyethylene terephthalate.

The surface of the opaque substrate may, for example, also be treated chemically in order to be better able to be bonded to the embedding material. The surface of the opaque substrate has preferably been treated by means of plasmas, especially with oxygen plasmas. The opaque substrate is more preferably treated when the opaque substrate adheres poorly when untreated.

The opaque substrate applied to the underside of the solar module preferably serves as a weather-resistant protective layer which forms the backside of the solar module (backside lamination).

Suitable solar cells are all solar cells known to those skilled in the art. Suitable solar cells are, for example, silicon cells, which may be thick-layer cells (mono- or polycrystalline cells) or thin-layer cells (amorphous silicon or crystalline silicon); III-V semiconductor solar cells (Ga—As cells); II-VI semiconductor solar cells (CdTe cells); CIS cells (copper indium diselenide or copper indium disulphide) or CIGS cells (copper-indium-gallium-diselenide); organic solar cells, dye cells (Grazel cells) or semiconductor electrolyte cells (e.g. copper oxidefNaCl solution); preference being given to using silicon cells. It is possible to use all types of silicon cells known to those skilled in the art, for example monocrystalline cells, polycrystalline cells, amorphous cells, microcrystalline cells or tandem solar cells, which are formed, for example, from a combination of polycrystalline and amorphous cells. Preference is given to using polycrystalline and amorphous cells.

The structures of the aforementioned solar cells are known to those skilled in the art.

In addition to thick-layer cells, it is possible to use thin-layer cells, concentrator cells, electrochemical dye solar cells, organic solar cells or fluorescent cells. In addition, it is possible to use flexible solar cells.

Suitable processes for producing the solar cells are known to those skilled in the art.

The scope of the invention encompasses all radical definitions, parameters and explanations given above and below, in general or within preferred ranges, in any combination with one another, i.e. also between the particular ranges and preferred ranges.

In step a) of the process according to the invention, the embedding materials are preferably laminated independently with the transparent substrates or the opaque substrates to give a transparent or/and opaque component. The procedure in step a) of the process according to the invention is preferably to take the preferably cleaned transparent or/and opaque substrate as the starting point. The embedding material is generally produced by the processes known to those skilled in the art, for example by coextrusion, extrusion (cast extrusion, flat-film extrusion) or calandering, and applied as a film to the transparent or/and opaque substrate. The embedding material is optionally cut to size and positioned on the substrate. This is followed by lamination, for example by processes known to those skilled in the art, for example standard vacuum lamination. In the course of lamination, the embedding material forms a transparent polymer layer on the transparent or/and opaque substrate, which is firmly bonded to the substrate. This transparent polymer layer has, for example, a thickness of 1 μm to 1000 μm. The transparent polymer layer after the lamination in step a) of the process according to the invention preferably has a thickness of 100 μm to 700 μm, more preferably of 200 μm to 500 μm.

The lamination in step a) of the process according to the invention can be performed, for example, at temperatures of 140 to 220° C. Preference is given to effecting the lamination from step a) of the process according to the invention at a temperature of 150° C. to 210° C., more preferably at a temperature of 160° C. to 180° C.

For example, the transparent or/and opaque substrate may be completely surrounded by the embedding material. The embedding material may, however, also be applied only on the top side or the bottom side of the transparent substrate or/and of the opaque substrate. In step a) of the process according to the invention, the embedding material is preferably applied only to one side of the transparent substrate or/and of the opaque substrate.

Step b) of the process according to the invention is preferably performed by contacting the components produced in step a) of the process according to the invention successively with at least one solar cell. For example, the transparent component produced in step a) of the process according to the invention can be taken as the starting point. The solar cells are between the transparent polymer materials of the transparent and opaque components. The solar cell can be positioned, for example, automatically by means of robots or manually. Thereafter, the transparent and opaque components and at least one solar cell can be laminated. However, it is likewise possible first to apply the solar cells to the transparent polymer material of the opaque component produced in step a) of the process according to the invention. It is then possible to apply the transparent polymer material of the transparent component produced in step a) of the process according to the invention to the surface of the solar module which is then still uncovered. Thereafter, the transparent and opaque components and at least one solar cell could then be laminated. Preferably, the transparent component produced in step a) of the process according to the invention is taken as the starting point. Thereafter, the solar cells are then positioned on the transparent polymer material, preferably in an automated manner by means of robots. Thereafter, the opaque component is preferably then applied by the side with the transparent polymer material thereon. This is preferably followed by lamination to give the composite.

In one embodiment of the invention, the solar module comprises a plurality of solar cells, which are then joined to one another by means of solder strips to form “strings”. Several strings are frequently connected to one another by means of transverse connectors. In a preferred embodiment of the process according to the invention, the solar cells, before being contacted with a component produced in step a) of the process according to the invention, are joined by means of solder strips to form individual strings. The solar cells are preferably joined by means of the solder strips before being contacted with the transparent component. Preferably, transverse connectors which connect the individual strings to one another and lead to a connection socket are subsequently positioned and brought into contact. Then the opaque component produced in step a) of the process according to the invention is applied to the solar module by the side with the transparent polymer material thereon. The positioning can be effected, for example, automatically and preferably by means of robots. This is preferably followed by the lamination to form the composite.

The lamination in step b) of the process according to the invention is effected preferably at temperatures of 140° C. to 220° C., preferably at temperatures of 150° C. to 210° C. and most preferably at temperatures of 160° C. to 180° C.

The lamination in step a) and/or step b) of the process according to the invention is effected by means of pressure or/and heat by the processes known to those skilled in the art, for example standard vacuum lamination. Preference is given to effecting the lamination in step a) and/or step b) of the process according to the invention by means of heat under reduced pressure.

The lamination in step b) of the process according to the invention achieves embedding of the solar cells into the transparent polymer layer and fixed bonding to the transparent substrate and the opaque substrate. Subsequently, a connection socket is preferably attached and the solar module is framed with the aid, for example, of an aluminium frame.

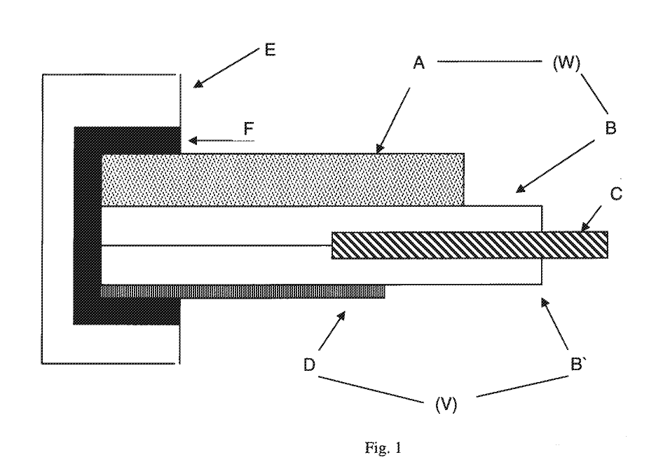

For example and with preference, the solar modules produced in the process according to the invention have the following structure (see also FIG. 1/1):
i) component (W) consisting of a transparent substrate A with a frontside and backside, the frontside being the side facing the sun in the finished solar module, and a transparent polymer layer B applied to the back side of the transparent substrate;
ii) one or more solar cells C positioned between the transparent polymer layers B and B′;
iii) component (V) consisting of an opaque substrate D, the opaque substrate D being bonded to the solar cell(s) C via the transparent polymer layer B′ in the finished solar module.

The solar cells C are more preferably embedded into the transparent polymer layers B and/or B′.

The transparent polymer layers B and/or B′ arise in the course of lamination of the embedding material to the substrate in step a) of the process according to the invention.

Suitable transparent polymer layers B and B′ consist of the above-defined α-olefin-vinyl acetate copolymers with a vinyl acetate content of ≧25% by weight, especially ethylene-vinyl acetate copolymers with a vinyl acetate content of ≧25% by weight; particularly suitable polymer layers B and B′ consist of ethylene-vinyl acetate copolymers with a vinyl acetate content of ≧40% by weight.

For example and with preference, components (W) and (V) are produced by the process according to the invention in step a). Preferably, component (W) is produced by laminating one side of a transparent substrate A to the embedding material consisting of at least one α-olefin-vinyl acetate copolymer, as a result of which the embedding material becomes the transparent polymer layer. Component (V) is preferably produced by laminating an opaque substrate D, more preferably a weather-resistant protective layer, with the embedding material consisting of at least one α-olefin-vinyl acetate copolymer in step a) of the process according to the invention. This step forms the transparent polymer layer from the embedding material. Particular preference is given to using an ethylene-vinyl acetate copolymer with a vinyl acetate content of ≧40% by weight in the production of components (W) and (V) in step a) of the process according to the invention.

The transparent substrate A is preferably laminated with the embedding material to give the new component (W) in such away that the transparent polymer layer B on the transparent substrate A is applied on the underside, i.e. the side facing toward the solar cells. The opaque substrate D is preferably laminated with the embedding material to give the new component (V) in such a way that the opaque substrate D is coated with the transparent polymer material B′ on the side facing toward the solar cells.

The solar cells are preferably applied on the underside to the component (W) produced in step a) of the process according to the invention. The solar cells are preferably first joined to one another by means of solder strips and then positioned. Thereafter, component (V) is applied by the side with the transparent polymer material B′ thereon. Preferably, transverse connectors which connect the individual strings to one another and lead to a connection socket are then positioned and brought into contact. The positioning is effected automatically by means of robots. This is followed by the lamination in step b) of the process according to the invention. Thereafter, it is optionally possible to mount further components known to those skilled in the art, for example seals, aluminium profile frames and electrical connection terminals, to the solar module. These components and the installation thereof are known to those skilled in the art.

The process according to the invention may also serve to produce solar modules which have another structure than the preferred structure mentioned above. Examples are glass-glass modules, concentrator modules in which the sunlight is concentrated onto smaller solar cells with the aid of a lens, and fluorescence collectors.

The process according to the invention has the advantage that solar modules are produced efficiently, since components can be fixed and laminated more efficiently, thus reducing the number of incorrectly produced solar modules.

FIG. 1 shows an example of a solar module produced by the process according to the invention.

In FIG. 1, the labels mean:

Component (W)
A transparent substrate
B transparent polymer material formed from at least one α-olefin-vinyl acetate copolymer and optionally further additives, preferably an ethylene-vinyl acetate copolymer, more preferably an ethylene-vinyl acetate copolymer with the Levamelt® name from Lanxess Deutschland GmbH;
C solar cells;

Component (V)
B transparent polymer material formed from at least one α-olefin-vinyl acetate copolymer and optionally further additives, preferably an ethylene-vinyl acetate copolymer, preferably an ethylene-vinyl acetate copolymer with the Levamelt® name from Lanxess Deutschland GmbH;
D opaque substrate or protective layer;
E frame, preferably an aluminium profile frame;
F seal.

Component (W) comprises components A and B. Component (V) comprises components B′ and D. It is also possible to use the process according to the invention to produce solar modules which have no components E and F. More particularly, component E can be dispensed with in the case of flexible solar modules.

Suitable components A, B, B′, C, D and E have already been described in detail above. Suitable seals F are known to those skilled in the art.

What is claimed is:

1. Process for producing solar modules, characterized in that,
in a step a),
a transparent or opaque substrate is laminated with an embedding material composed of at least one α-olefin-vinyl acetate copolymer having a vinyl acetate content of ≧25% by weight, based on the total weight of the α-olefin-vinyl acetate copolymer, to give a component and,
in a second step b),
a component produced from transparent substrate in step a) and a component produced from opaque substrate in step a) are laminated with at least one solar cell positioned between the transparent and the opaque component to give the solar module.

2. Process according to claim 1, characterized in that the embedding material comprises at least one additive.

3. Process for producing solar modules according to claim 1 or 2, characterized in that the embedding material comprises an α-olefin-vinyl acetate copolymer at 90% by weight to 100% by weight and 10 to 0% by weight of an additive, based on the total weight of the embedding material.

4. Process for producing solar modules according to one or more of claims 1 to 3, characterized in that the embedding material contains the additive at 0% by weight to 20% by weight, based on the total weight of the embedding material.

5. Process for producing solar modules according to one or more of claims 1 to 4, characterized in that an α-ethylene-vinyl acetate copolymer with a vinyl acetate content of ≧40% by weight, based on the total weight of the α-ethylene vinyl acetate copolymer, is used.

6. Process for producing solar modules according to one or more of claims 1 to 5, characterized in that the additives are selected from the group of peroxides, light stabilizers, silanes, aging stabilizers, benzophenones, triallyl cyanurate or triallyl isocyanurate, or from mixtures of these additives.

7. Process for producing solar modules according to one or more of claims 1 to 6, characterized in that the transparent substrate used is glass, polyvinyl fluoride polymer laminates or polyethylene terephthalate, or mixtures of these materials.

8. Process for producing solar modules according to one or more of claims 1 to 7, characterized in that the opaque substrate used is polyester, polyvinylidene fluoride or polyethylene terephthalate, or mixtures of these materials.

9. Process for producing solar modules according to one or more of claims 1 to 8, characterized in that the embedding material after the lamination in step a) according to claim 1 has a thickness between 200 μm and 500 μm on the substrate.

10. Process for producing solar modules according to one or more of claims 1 to 9, characterized in that the lamination in step a) or/and in step b) is performed at temperatures of 160° C. to 180° C.
